(19) United States
(12) Patent Application Publication
(10) Pub. No.: US 2007/0013409 A1
(43) Pub. Date: Jan. 18, 2007

(54) Digitally controlled high-voltage power supply and method therefor

(75) Inventor: Young-min Chae, Suwon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/430,963

(22) Filed: May 10, 2006

(30) Foreign Application Priority Data
Jul. 13, 2005 (KR) 2005-63417

(51) Int. Cl. G01R 31/36

(52) U.S. Cl. 324/771

(57) ABSTRACT

A digitally controlled high-voltage power supply and a method thereof are provided. The high-voltage power supply includes an output unit having a primary winding connected in parallel with a capacitor and a secondary winding inducing a voltage by current flowing in the primary winding. A switching unit switches on and off current flowing into the output unit with an LC resonance voltage across the primary winding. A digital interface unit provides communication interface for certain formats. A digital control unit controls the switching unit to be switched on and off, depending on control data input through the digital interface unit and the LC resonance voltage across the primary winding. Accordingly, switching operations are performed at time voltages across a switching device that fall in voltage-minimized intervals, which reduce an amount of heat generation from the switching device and switching device loss caused by the heat generation.

### CROSS-REFERENCE TO RELATED APPLICATIONS

This application claims the benefit under 35 U.S.C. § 119(a) of Korean Patent Application No. 2005-63417, filed on Jul. 13, 2005, the entire disclosure of which is hereby incorporated by reference.

### BACKGROUND OF THE INVENTION

1. Field of the Invention

The present invention relates to a digitally controlled high-voltage generation device and method therefor. More particularly, the present invention relates to a digitally controlled high-voltage generation device and method providing an improved switching operation timing.

2. Description of the Related Art

Image-forming devices refer to devices for printing images corresponding to input data for original images on a recording medium such as paper. Examples of such image-forming devices can be printers, photocopiers, facsimile machines and the like. An electro-photographic process is employed for image-forming devices such as laser printers, LED print head (LPH) printers, facsimile machines, and the like. The electro-photographic image-forming devices perform printout jobs through processes such as electrical charging, exposure to light, developing, transfer, and fusing.

FIG. 1 is a cross-sectioned view for schematically showing a conventional electro-photographic image-forming device. In FIG. 1, the electro-photographic image-forming device comprises a photosensitive drum 1, charge roller 2, laser scanning unit (LSU) 3, development roller 4, transfer roller 5, control unit 6, and high-voltage power supply (HVPS) 70.

In printout operations of an electro-photographic image-forming device comprising such a structure in FIG. 1, the high-voltage power supply 70 applies certain voltages to the charge roller 2, development roller 4, and transfer roller 5 according to controls of the control unit 6. The charge roller 2 uniformly charges the surface of the photosensitive drum 1 with a charging voltage applied by the HVPS 70. Further, a light beam of the LSU 3, corresponding to image data input from the control unit 6, scans across the photosensitive drum 1. Thus, an electrostatic latent image is formed on the surface of the photosensitive drum 1.

Next, the electrostatic latent image formed on the surface of the photosensitive drum 1 is converted into a toner image by toner supplied by the development roller 4. The transfer roller 5 driven by a transfer voltage applied from the HVPS 70 transfers the toner image formed on the photosensitive drum 1 to a recording sheet of paper. Further, the toner image transferred to the recording sheet is fused on the paper by high heat and pressure of a fuser (not shown). The paper is externally discharged in a discharge direction (not shown) so that printout is completed.

As described above, the HVPS 70 is a core component for photocopiers, laser beam printers, facsimile machines, and the like, which enables text printout by forming high-voltage discharge over a printer drum or facsimile machine drum through instant conversion of a low voltage into a high voltage of a few hundred to few thousand voltages. The HVPS 70 is also used for a constant voltage source or a constant current source by sensing a voltage or current, depending on the HVPS 70 usage purpose.

FIG. 2 is a circuit for showing a conventional HVPS 70. In FIG. 2, the conventional HVPS 70 has a low-pass filter 10, voltage control unit 20, oscillation and voltage conversion unit 30, voltage-doubling unit 40, voltage-sensing unit 50 and protection unit 60.

A pulse width modulated (PWM) signal D(t), from an engine control unit or the like, is input to the HVPS. The low-pass filter 10 converts the PWM signal D(t) into a DC signal for an output through a two-stage RC filter. The PWM signal has an output voltage level determined according to its duty ratio, and the DC signal is used as a reference signal for output voltage controls.

The voltage control unit 20 has a differential circuit and a controller for amplifying an error signal for its operations. The voltage control unit 20 compares the DC signal output through the low-pass filter 10 to an actual output voltage as a feedback signal, and generates a driving signal for a transistor Q of the oscillation and voltage conversion unit 30.

The oscillation and voltage conversion unit 30 controls an amount of current to the base of the transistor Q, based on an output signal of the voltage control unit 20. The oscillation and voltage conversion unit 39 also changes a voltage across a primary winding of a voltage conversion unit as a voltage across the emitter and collector of the transistor varies, so that a voltage is induced across a secondary winding of the voltage conversion unit having a high coil turn ratio.

The voltage-doubling unit 40 uses diodes D1 and D2 for rectification and capacitors C4 and C5 for voltage doubling and smoothing, and generates a final high DC voltage from an AC voltage induced across the secondary winding of the voltage conversion unit. Further, the voltage-sensing unit 50 and protection unit 60 detect an actual output voltage, and generate a feedback signal to the voltage control unit 20, thereby preventing an abnormal voltage from being applied.

FIG. 2 shows a circuit for the HVPS 70 for generating a high voltage to a development unit for one specific channel. However, the HVPS 70 requires extra channels in order for certain high voltages to be applied to the charging roller 2, development roller 4, and transfer roller 5.

The conventional HVPS 70 as described above uses an analog control method in order to precisely control individual channel outputs, so compensation is required for errors caused by differences between characteristics of components, such as, a RC filter and voltage-controlling components.

Further, the HVPS 70 uses a plurality of components, which prevents cost reduction, and may create an overall malfunction at the time individual components become defected due to external factors. Further, the transistor used as a switching component in the oscillation and voltage conversion unit 30 operates in a linear region. Therefore, the transistor acquires heat-generating properties.

Furthermore, as shown in FIG. 2, the conventional HVPS 70 uses a plurality of components, which increases the man hour and work time in an assembly process, requires space on the printed circuit board (PCB) to be secured for the plurality of components, and deters control of an output voltage since the components are fixed to the PCB.

In order to overcome the above described problems, the conventional HVPS 70 uses a digital control mode. However, the application-specific integrated circuit (ASIC)-based HVPS circuit usually contains metal oxide semiconductor field effect transistor (MOSFET) devices as switching devices. Since the ASIC is an integrated circuit for analog devices, the MOSFET devices generate substantial heat during switching operations in a linear region, which causes damage to the switching devices.

### SUMMARY OF THE INVENTION

An aspect of exemplary embodiments of the present invention is to address at least the above problems and/or disadvantages and to provide at least the advantages described below. Accordingly, an aspect of exemplary embodiments of the present invention is to provide a high-voltage power supply and method thereof, capable of determining an improved switching operation timing.

An HVPS ASIC applied to exemplary embodiments of the present invention requires a switching circuit topology having less heat generation, in order to determine improved switching operation timings of switching devices. Therefore, when a switching device performs switching in an interval once a voltage across the switching device becomes the lowest, the switching device generates less heat, during a time of which the switching device has improved operation timing.

The foregoing and other objects and advantages of exemplary embodiments of the present invention are substantially implemented by providing a high-voltage power supply, whereby an output unit comprises a primary winding connected in parallel with a capacitor and a secondary winding inducing a voltage by current flowing in the primary winding. A switching unit switches on and off current flowing into the output unit with an LC resonance voltage across the primary winding. A digital interface unit provides communication interface for certain formats. A digital control unit controls the switching unit to be switched on and off depending on control data input through the digital interface unit and the LC resonance voltage across the primary winding. The capacitor and primary winding form a resonance circuit. The switching unit switches on and off current during an interval in which the LC resonance voltage is minimized.

The output unit may comprise a resistor connected in series with the capacitor and primary winding.

A switching device of the switching unit may comprise a MOSFET.

The digital control unit controls the switching unit to be switched on and off by a feedback signal of an output value of the output unit.

The switching unit, digital interface unit and digital control unit may be implemented in one application-specific integrated circuit (ASIC) chip.

The foregoing and other objects and advantages of exemplary embodiments of the present invention are substantially implemented by providing an image-forming device for performing printout by using a high-voltage power supply, where an output unit comprises a primary winding L connected in parallel with a capacitor C, and a secondary winding inducing current by a current of the primary winding. A switching unit switches on and off current flowing into the output unit with an LC resonance voltage across the primary winding. A digital interface unit provides a communication interface for certain formats. A digital control unit controls the switching unit to be switched on and off, depending on control data input through the digital interface unit and the LC resonance voltage across the primary winding. The foregoing and other objects and advantages of exemplary embodiments of the present invention are substantially implemented by providing a method for a high-voltage power supply, where voltages varying with LC resonance across the primary winding connected in parallel with a capacitor are detected. Intervals are calculated in which an LC resonance voltage across the primary winding is minimized. Current flowing into the capacitor C and the primary winding L is switched on and off, depending on the calculated intervals in which the LC resonance voltage is minimized. The capacitor and the primary winding form a resonance circuit. A voltage is dropped across a resistor connected in series with the capacitor and primary winding.

Further, in an exemplary implementation, a MOSFET switches on and off current flowing into the capacitor C and the primary winding L.

In another exemplary implementation, a feedback signal of an output value, by a voltage induced across a secondary winding, switches the current on and off.

The foregoing and other objects and advantages of exemplary embodiments of the present invention are substantially implemented by providing an image-forming device for printout by using a high-voltage power supply, where voltages varying with LC resonance across a primary winding connected in parallel with a capacitor are detected. Intervals are calculated in which the LC resonance voltages across the primary winding are minimized. Current flowing into the capacitor C and primary winding L is switched on and off, depending on the calculated intervals in which the LC resonance voltages are minimized.

### BRIEF DESCRIPTION OF THE DRAWINGS

The above aspects and other objects, features, and advantages of certain exemplary embodiments of the present invention will be more apparent from the following description taken in conjunction with the accompanying drawings, in which:

FIG. 1 is a view for schematically showing a conventional image-forming device;

FIG. 2 is a circuit diagram for showing a conventional high-voltage power supply;

FIG. 3 is a block diagram for showing a high-voltage power supply according to an exemplary embodiment of the present invention;

FIG. 4 is a view for schematically showing a structure of a first output unit according to an exemplary embodiment of the present invention;

FIG. 5A is a graph for showing voltages varying with resonance across a primary winding according to an exemplary embodiment of the present invention;

FIG. 5B is a graph for showing voltages varying at a gate of a MOSFET according to an exemplary embodiment of the present invention;

FIG. 5C is a graph for showing voltages varying across a drain and source of the MOSFET according to an exemplary embodiment of the present invention; and

FIG. 5D is a graph for showing electric currents varying at the drain of the MOSFET according to an exemplary embodiment of the present invention.

Throughout the drawings, the same drawing reference numerals will be understood to refer to the same elements, features, and structures

### DETAILED DESCRIPTION OF EXEMPLARY EMBODIMENTS

The matters defined in the description such as a detailed construction and elements are provided to assist in a comprehensive understanding of the embodiments of the invention. Accordingly, those of ordinary skill in the art will recognize that various changes and modifications of the embodiments described herein can be made without departing from the scope and spirit of the invention. Also, descriptions of well-known functions and constructions are omitted for clarity and conciseness.

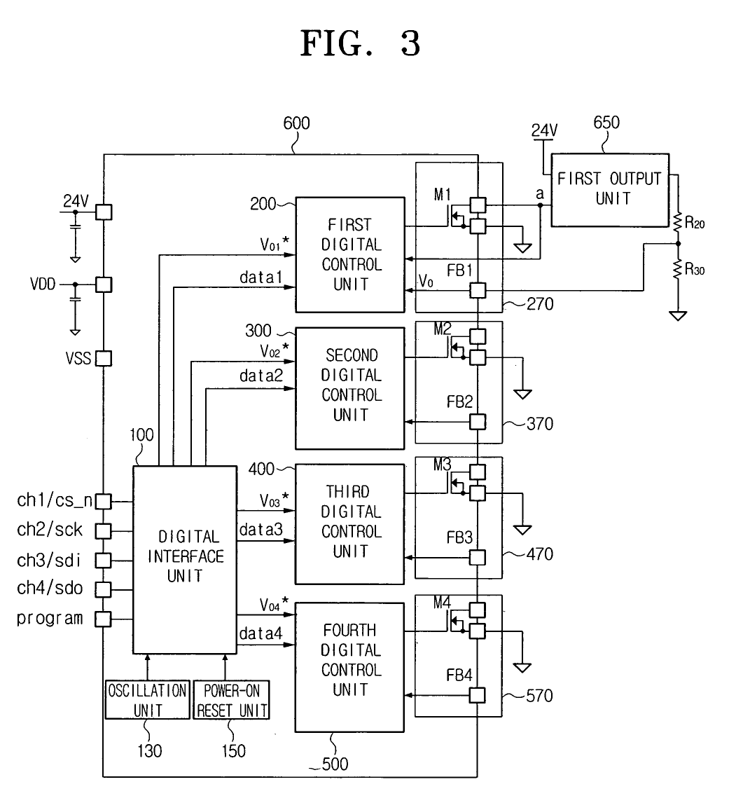

FIG. 3 is a block diagram for showing a high-voltage power supply (HVPS) 600 according to an exemplary embodiment of the present invention. In FIG. 3, the HVPS 600 comprises a digital interface unit 100, oscillation unit 130, power-on reset unit 150, first to fourth digital control units 200, 300, 400, and 500, respectively, and first to fourth switching units 270, 370, 470, and 570, respectively.

The first to fourth switching units 270, 370, 470, and 570 are respectively connected to an output unit provided with a voltage conversion unit, and a voltage-doubling unit. For convenience of explanation, but by no means as a limitation, the first switching unit 270 of FIG. 3 is shown to be connected to the first output unit 650.

The digital interface unit 100 inputs, from an engine control unit or the like, control data used for controlling a waveform or magnitude of an output voltage. The control data is data of PWM format in which an output voltage level is determined according to a duty ratio, or data of a format for communication with a universal asynchronous receiver/transmitter (UART), serial peripheral interface (SPI) as an interface enabling data to be exchanged in serial communication between two devices, or serial communication interface such as a bi-directional serial bus of 12C.

The digital interface unit 100 converts the control data input from the engine control unit or the like into a predetermined format. The converted control data is delivered to the first to fourth digital control units 200, 300, 400, and 500, respectively, so that the converted control data can be used as time constants data1, data2, data3, and data4 for determining an output voltage waveform, and as reference voltage values V01*, V02*, V03*, and V04* for determining an output voltage magnitude.

The first to fourth digital control units 200, 300, 400, and 500, having the same structure and function, compare the reference voltage values VO1*, V02*, V03*, and V04* received from the digital interface unit 100 to signals VO fed back with actual output voltages of individual channels detected. As a result of the comparison, the digital control units 200, 300, 400, and 500 use the control reference value as a driving signal to a corresponding switching device out of the first to fourth switching units 270, 370, 470, and 570.

The first to fourth switching units 270, 370, 470, and 570 are built in one ASIC chip, and use MOSFETs M1, M2, M3, and M4 as a switching device, respectively. The first to fourth switching units 270, 370, 470, and 570 switches on and off driving signals respectively output from the first to fourth digital control units 200, 300, 400, and 500, and applied to the gates of MOSFETs, in order to control current flowing in a primary winding of the voltage conversion unit connected in series with the drains. As described above, since the MOSFETs, as switching devices, are used for transistors, it is unnecessary to use a heat sink for preventing transistors from heat generation.

The HVPS 600 is provided with an oscillation unit 130 as a clock signal generator and power-on reset unit 150 for supplying a reset signal once power is on. The HVPS 600 is structured for a voltage of 24V for high-voltage supply and a voltage of VDD as an IC-driving voltage to be supplied.

The above structure controls the output units for individual channels according to control data transferred from the engine control unit or the like, and generates a high voltage.

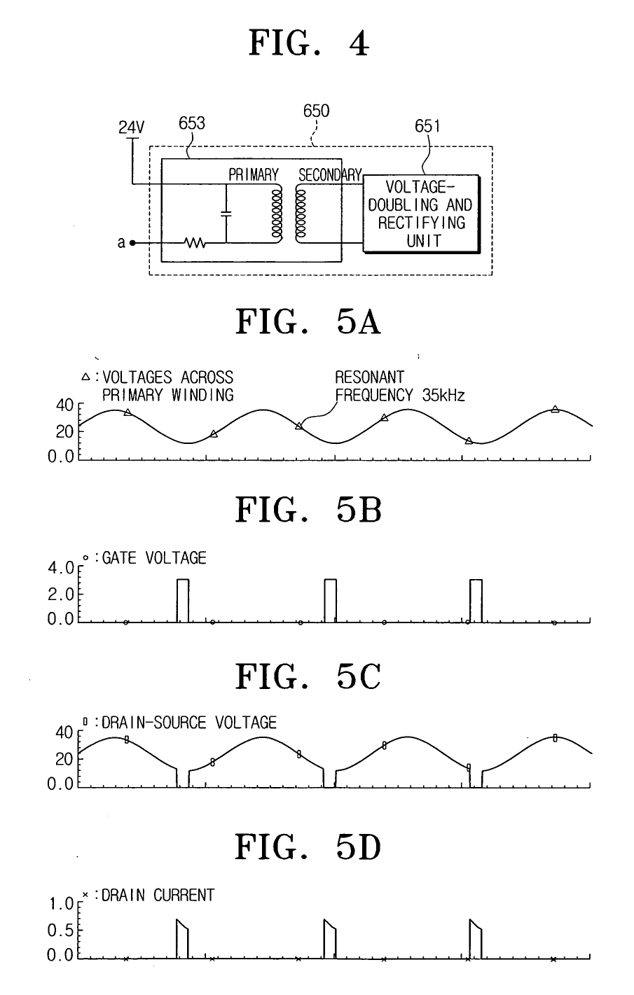

FIG. 4 is a view for schematically showing a structure of the first output unit according to an exemplary embodiment of the present invention. In FIG. 4, the first output unit 650 comprises a voltage conversion unit 653 and a voltage-doubling and rectifying unit 651.

The voltage conversion unit 653 is connected in series with the first switching unit 270, and has primary and secondary windings. A capacitor having capacitance of a certain magnitude is connected in parallel with the primary winding. In the voltage conversion unit 653, the capacitance and the primary winding form an LC resonance circuit.

If the first switching unit 270 is switched on, current flows into the primary winding, so current may be induced in the secondary winding. As a result, energy is delivered to the voltage-doubling and rectifying unit 651.

That is, if current flows in the primary winding, the capacitor connected in parallel with the secondary winding of the voltage conversion unit 653 is charged with a high voltage that is proportional to a turn ratio of the primary winding to the secondary winding.

Next, if the first switching unit 270 is switched off, resonant current is circulated due to a resonance phenomenon of the capacitor and primary winding forming the resonance circuit with the voltage conversion unit 653, in which an output voltage of the first output unit 650 is controlled.

That is, if the first switching unit 270 is switched off, an output diode connected in series with the secondary winding is forward-biased so that a final output voltage is increased. The output voltage is used as a final output voltage after a voltage increases through the voltage-doubling unit.

Next, if the first switching unit 270 is switched on, heat generation is increased from the first switching unit 270 as a voltage across switching terminals of the first switching unit 270 increases, which causes switching loss of the first switching unit 270. In an exemplary implementation, the voltage across the switching terminals of the first switching unit 270 is substantially similar to the voltage across both ends of the primary winding.

Therefore, when the first switching unit 270 is switched on at the time the voltage across the switching terminals of the first switching unit 270 becomes minimized, the heat generation amount from the first switching unit 270 and switching loss caused by the heat generation can be minimized.

FIG. 5A is a graph for showing voltages varying with resonance across the primary winding according to an exemplary embodiment of the present invention. The voltages form a sinusoidal wave across the primary winding upon resonance of the resonance circuit having the voltage conversion unit 653, as shown in FIG. 5A. The voltages are resonance voltages when a resonant frequency is 35 KHz. In an exemplary implementation, the resonant frequency can be adjusted by adjusting a reactance value of the primary winding and a capacitance value of the capacitor connected in parallel with the primary winding.

Upon resonance, a voltage having the same magnitude as the voltage across the primary winding is formed across a MOSFET as a switching device of the first switching unit 270. The first digital control unit 200 detects the corresponding voltage.

The first digital control unit 200 detects an interval in which the detected voltage is minimized. The voltage-minimized interval width corresponds to a time period for which a MOSFET remains switched on, wherein the MOSFET is determined based on control data from the digital interface unit 100. The time at which a voltage across the MOSFET is minimized corresponds to a center point of the above voltage-minimized interval.

FIG. 5B is a graph for showing voltages varying at the gate of a MOSFET according to an exemplary embodiment of the present invention. In FIG. 5B, the gate voltages formed in the voltage-minimized interval for a voltage detected by the first digital control unit 200 may vary. The voltage-minimized interval for a voltage detected by the first digital control unit 200 becomes a gate voltage pulse width in FIG. SB. Accordingly, the MOSFET is switched on when a gate voltage is increased, and the MOSFET is switched off when the gate voltage is decreased.

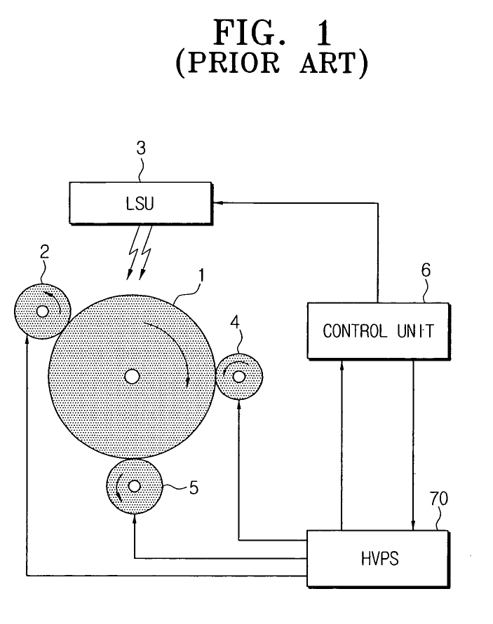

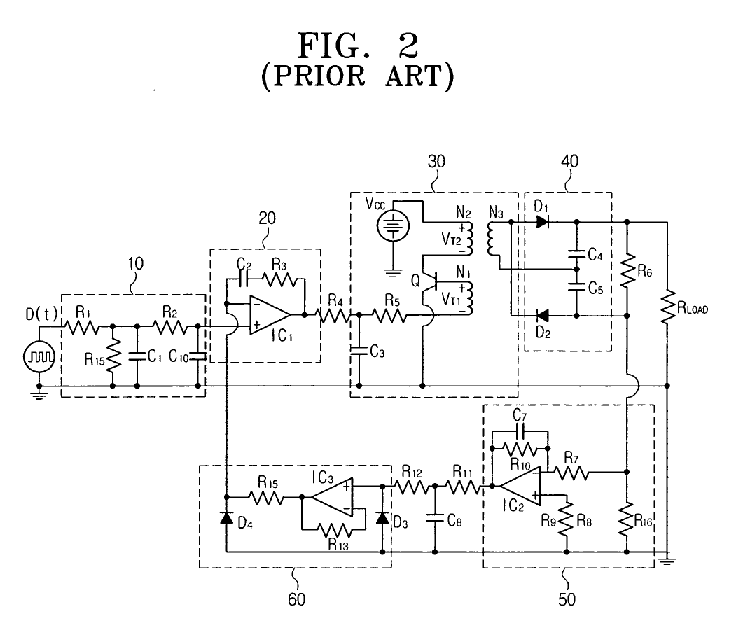

FIG. 5C is a graph for showing voltages across the drain and source of the MOSFET according to an exemplary embodiment of the present invention. In FIG. 5C, voltages across the drain and source of the MOSFET corresponds to voltages varying with resonance across the primary winding, as shown in FIG. 1A. If voltages fall to “0” during a voltage-increasing interval for the voltages at the gate of the MOSFET as shown in FIG. 5B, the voltage-increasing interval corresponds to the voltage-minimized interval for the voltages detected by the first digital control unit 200.

FIG. 5D is a graph for showing voltages varying at the drain of the MOSFET according to an exemplary embodiment of the present invention. In FIG. 5D, drain current is formed during the intervals in which the voltages across the drain and source shown in FIG. 5C are “0”. In this instance, current is applied to the voltage conversion unit 653.

In an exemplary the embodiment of the present invention, an output value of the first output unit 650 is fed back to the first digital control unit 200. The first digital control unit 200 can control the first switching unit 270 to be switched on or off by comparing the feedback signal to the control data input from the digital interface unit 100.

Since a switching device according to an exemplary implementation of the present invention can be switched on and off while voltages across the switching device are in the voltage-minimized interval, switching loss is minimized and an output voltage is controlled.

The voltage conversion unit 653 may include a resistor having a certain resistance magnitude which is connected in series with the above LC resonance circuit. Since the resistor drops a voltage in order to decrease a voltage across a switching device, the switching loss is minimized. However, the resistance magnitude of the above resistor can be properly set, depending on exemplary implementations of the present invention.

The description relating to the structure and functions of the first digital control unit 200 and first output unit 650 is applicable to, for example, the second to fourth digital control units 300, 400, and 500 and second to fourth output units (not shown).

As described above, exemplary embodiments of the present invention cause switching operations to be performed at a time voltages across a switching device fall in voltage-minimized intervals, thereby reducing an amount of heat generation from the switching device and switching device loss caused by the heat generation.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A high-voltage power supply, comprising:
an output unit comprising a primary winding connected in parallel with a capacitor, and a secondary winding inducing a voltage by current flowing in the primary winding;
a switching unit for switching on and off current flowing into an output unit with an LC resonance voltage across the primary winding;
a digital interface unit for providing communication interface; and
a digital control unit for controlling the switching unit to be switched on and off based on control data input through the digital interface unit and the LC resonance voltage across the primary winding.

2. The high-voltage power supply as claimed in claim 1, wherein the capacitor and the primary winding form a resonance circuit.

3. The high-voltage power supply as claimed in claim 1, wherein the switching unit switches on and off current during an interval in which the LC resonance voltage is minimized.

4. The high-voltage power supply as claimed in claim 1, wherein the output unit further comprises a resistor connected in series with the capacitor and the primary winding.

5. The high-voltage power supply as claimed in claim 1, wherein a switching device of the switching unit comprises a metal oxide semiconductor field effect transistor (MOSFET).

6. The high-voltage power supply as claimed in claim 1, wherein the digital control unit controls the switching unit to be switched on and off by a feedback signal of an output value of the output unit.

7. The high-voltage power supply as claimed in claim 1, wherein at least one of the switching unit, digital interface unit, and digital control unit is implemented in one application-specific integrated circuit (ASIC) chip.

8. An image-forming device comprising the high-voltage power supply as claimed in claim 1

9. A method for supplying a high-voltage, the method comprising:
detecting voltages varying with LC resonance across a primary winding of a high-voltage power supply, the primary winding being connected in parallel with a capacitor;
calculating intervals in which an LC resonance voltage across the primary winding is minimized; and
switching on and off current flowing into the capacitor and the primary winding, based on the calculated intervals in which the LC resonance voltage is minimized.

10. The method as claimed in claim 9, wherein the capacitor and the primary winding form a resonance circuit.

11. The method as claimed in claim 9, further comprising dropping a voltage across a resistor connected in series with the capacitor and the primary winding.

12. The method as claimed in claim 9, wherein the switching comprises utilizing a MOSFET which switches on and off the current flowing into the capacitor and the primary winding.

13. The method as claimed in claim 9, wherein the switching comprises switching on and off of the current by a feedback signal of an output value by a voltage induced across a secondary winding.

14. An image-forming method comprising:
detecting voltages varying with LC resonance across a primary winding of a high voltage power supply, the primary winding being connected in parallel with a capacitor;
calculating intervals in which the LC resonance voltages across the primary winding are minimized; and
switching on and off current flowing into the capacitor and the primary winding based on the calculated intervals in which the LC resonance voltages are minimized.
